(19) United States
(12) Patent Application Publication
(10) Pub. No.: US 2021/0065961 A1
(43) Pub. Date: Mar. 4, 2021

(54) ELECTRONIC DEVICE AND METHOD FOR UTILIZING SAME AS MAGNETIC BODY

(71) Applicant: Samsung Electronics Co., Ltd., Suwon-si, Gyeonggi-do (KR)

(72) Inventors: Woosup LEE, Suwon-si (KR); Jungsik PARK, Suwon-si (KR); Yongyoun KIM, Suwon-si (KR); Sehwan CHOI, Suwon-si (KR); Hyoseok NA, Suwon-si (KR); Soyoung LEE, Suwon-si (KR)

(21) Appl. No.: 16/958,360

(22) PCT Filed: Dec. 28, 2018
(86) PCT No.: PCT/KR2018/016923

§ 371 Date: Jun. 26, 2020

(30) Foreign Application Priority Data
Jan. 5, 2018 (KR) 10-2018-0001802

(51) Int. Cl. H01F 27/28; H05K 1/18; H05K 9/00; G06F 1/16

(52) U.S. Cl. CPC H01F 27/28; H05K 1/18; H05K 9/0084; H02J 7/02; H05K 2201/10098; H05K 2201/10128; G06F 1/1616

(57) ABSTRACT

An electronic device according to various embodiments of the present invention includes: at least one coil; a circuit board; and first member, corresponding to the at least one coil, disposed between the at least one coil and the circuit board, wherein the first member may be attached to or detached from a second member which is a metallic material. Other embodiments are also possible.

### TECHNICAL FIELD

Various embodiments of the disclosure relate to a method for utilizing an electronic device as a magnetic body and an electronic device that realizes the same.

### BACKGROUND ART

A portable electronic device such as a mobile phone may be driven by a rechargeable battery, and a wireless charging coil may be embedded to charge the battery wirelessly. Further, the portable electronic device may directly generate a frequency for short distance wireless communication with another electronic device, and a near field communication (NFC) coil and a magnetic secure transfer (MST) coil may be embedded to generate the frequency. The portable electronic device may perform a payment function in a payment system by using electromagnetic waves generated based on an NFC coil and an MST coil.

In order that the portable electronic device may support a wireless charging method of a battery, an attractor may be used, and in order that the portable electronic device may maintain the intensities of the electromagnetic waves for performing a payment function, a shielding sheet (e.g., for shielding electromagnetic waves) may be used. Generally, the attractor and the shielding sheet may have a magnetic property (e.g., magnetism or a magnetic force).

### DISCLOSURE OF INVENTION

### Technical Problem

A magnetic force may be generated between magnetic objects, and the magnetic objects may be attached to or detached from each other. Hereinafter, a magnetic object will be referred to as “a magnetic body”. A magnetic body (e.g., a first magnet) may be mounted at least partially in the interior of a portable electronic device, and may be attached to or detached from another external magnetic body (e.g., a second magnet).

In order to use the portable terminal as a magnetic body, a magnet may be mounted in the interior thereof. For example, a magnet may be mounted at an outskirt portion or a corner portion of the portable electronic device to fix the portable electronic device. As the magnet is mounted, an interior of the portable electronic device, in which another component (e.g., an antenna) is to be located, may become narrower.

According to various embodiments of the disclosure, an interior space of a portable electronic device, in which a magnet has been located, may be utilized by utilizing at least one component embedded in the portable electronic device as a magnetic body. According to the portable electronic device, at least one component embedded in advance in the portable electronic device may be utilized as one magnetic body while a magnet corresponding to a magnetic body is not mounted on the portable electronic device.

### Solution to Problem

In accordance with an aspect of the disclosure, an electronic device may include at least one coil, a circuit board, and a first member disposed between the at least one coil and the circuit board in correspondence to the at least one coil, and the first member is attached to a second member including a metallic material or is detached from the second member.

According to various embodiments, the electronic device may further include a first housing and a second housing defining an external appearance of the electronic device, a hinge unit connecting the first housing and the second housing such that the first housing and the second housing are folded, a first magnetic body disposed in the interior of the first housing, and a second magnetic body disposed in the interior of the second housing and magnetically coupled to the first magnetic body when the first housing and the second housing are folded.

According to various embodiments, the electronic device may further include a display divided into a first display area and a second display area and folded with respect to a border line between the first display area and the second display area, a circuit board including at least one coil in correspondence to the first display area, and a first member attached to the circuit board in correspondence to the at least one coil, and the first member may be attached the second member that is a metallic material included in the second display area when the display is folded or is detached from the second member.

### Advantageous Effects of Invention

According to various embodiments of the disclosure, an electronic device may be utilized as a magnetic body. In detail, according to the electronic device, at least one embedded component may be utilized as one magnetic body. According to the electronic device, because a magnet corresponding to a magnetic body is not directly mounted, an arrangement space for the magnet can be secured. According to various embodiments of the disclosure, the secured space can be utilized to dispose an additional antenna. According to various embodiments of the disclosure, an interior space of the electronic device can be utilized more efficiently.

### BRIEF DESCRIPTION OF DRAWINGS

FIG. 1 is a perspective view of a front surface of an electronic device according to an embodiment.

FIG. 2 is a perspective view of a rear surface of an electronic device according to an embodiment.

FIG. 3 is an exploded perspective view of an electronic device according to an embodiment.

FIG. 4 is a view illustrating an internal structure of an electronic device, in which a plurality of coils are embedded, according to various embodiments.

FIGS. 5A and 5B are views illustrating the interior of an electronic device, in which a space for disposing a magnet is secured, according to various embodiments.

FIG. 6 is an exemplary view of a method of disposing a magnet in a front cover of an external case and utilizing a metallic material embedded in an electronic device as a magnetic body according to various embodiments when the front cover is folded to be adjacent to a rear surface of the electronic device.

FIG. 7 is an exemplary view of a method of disposing a magnet in a rear cover of an external case and utilizing a metallic material embedded in an electronic device as a magnetic body according to various embodiments.

### MODE FOR THE INVENTION

Hereinafter, the disclosure is described with reference to the accompanying drawings. Although various example embodiments are illustrated in the drawings and related detailed descriptions are discussed in the disclosure, the disclosure may have various modifications and several embodiments. However, certain embodiments of the disclosure are not limited to a specific implementation form and it should be understood that the disclosure includes all changes and/or equivalents and substitutes included in the certain embodiments of the disclosure. In connection with descriptions of the drawings, similar components are designated by the same reference numeral.

In certain embodiments of the disclosure, the terms such as “include,” “have,” “may include,” or “may have” may be construed to denote a certain characteristic, number, step, operation, constituent element, component or a combination thereof, but may not be construed to exclude the existence of or a possibility of addition of one or more other characteristics, numbers, steps, operations, constituent elements, components or combinations thereof.

In certain embodiments of the disclosure, the expression “or” or “at least one of A or/and B” includes any or all of combinations of words listed together. For example, the expression “A or B” or “at least A or/and B” may include A, may include B, or may include both A and B.

The expression “1,” “2,” “first,” or “second” used in certain embodiments of the disclosure may be used for various components of the certain embodiments but does not limit the corresponding components. For example, the above expressions do not limit the sequence and/or importance of the components. The expressions may be used for distinguishing one component from other components. For example, a first user device and a second user device indicate different user devices although both of them are user devices. For example, without departing from the scope of the disclosure, a first structural element may be referred to as a second structural element. Similarly, the second structural element also may be referred to as the first structural element.

When it is stated that a component is “(operatively or communicatively) coupled to” or “connected to” another component, the component may be directly coupled or connected to another component or a new component may exist between the component and another component. On the other hand, when it is stated that a component is “directly coupled to” or “directly connected to” another component, a new component does not exist between the component and another component.

In the disclosure, the expression “configured (or set) to do” may be used interchangeably with, for example, “suitable for doing,” “having the capacity to do,” “designed to do,” “adapted to do,” “made to do,” or “capable of doing.” The expression “configured (or set) to do” may not necessarily be used to refer to only something in hardware for which it is “specifically designed to do.” Instead, the expression “a device configured to do” may indicate that the device is “capable of doing” something with other devices or parts. For example, the expression “a processor configured (or set) to do A, B and C” may refer to a dedicated processor (e.g., an embedded processor) or a generic-purpose processor (e.g., CPU or application processor or any other processing circuitry) that may execute one or more software programs stored in a memory device to perform corresponding functions.

According to certain embodiments, the terms used in the disclosure are only used to describe specific embodiments, and may not be intended to limit the scope of other embodiments. Singular expressions may include plural expressions, unless the context clearly indicates otherwise. Terms used herein, including technical or scientific terms, may have the same meanings as commonly understood by those skilled in the art described in the disclosure. Among the terms used in the disclosure, terms defined in commonly used dictionaries should be interpreted as meanings identical or similar to meanings in the context of related technologies. The terms should not be interpreted in an idealized or overly formal sense, unless explicitly defined in the disclosure. Even terms defined in the disclosure cannot be interpreted to exclude embodiments of the disclosure.

According to certain embodiments, examples of the electronic device may include a smailphone, a tablet Personal Computer (PC), a mobile phone, a video phone, an electronic book reader, a desktop PC, a laptop PC, a netbook computer, a workstation, a server, a Personal Digital Assistant (PDA), a Portable Multimedia Player (PMP), an MP3 player, a medical device, a camera, and a wearable device, or the like, but is not limited thereto. Examples of the wearable device may include an accessory type device (such as, watch, ring, bracelet, ankle bracelet, necklace, glasses, contact lens, and Head-Mount Device (HMD)), a textile or clothes type device (such as electronic clothes), a body-attached type (such as skin pad and tattoo), and a bio-implemented type, or the like, but is not limited thereto.

According to an embodiment, examples of the electronic device may include a television, a Digital Video Disc (DVD) player, an audio player, a refrigerator, an air conditioner, a cleaner, an oven, a microwave oven, a laundry machine, an air purifier, a set-top box, a home automation control panel, a security control panel, a media box (such as Samsung HomeSync™, apple TV™, and google TV™), a game console (such as Xbox™ and PlayStation™), an electronic dictionary, an electronic key, a camcorder, and an electronic frame, or the like, but is not limited thereto.

According to an embodiment, examples of the electronic device may include a medical device (such as portable medical sensors (including glucometer, heart rate sensor, tonometer, and body thermometer), Magnetic Resonance Angiography (MRA) device, Magnetic Resonance Imaging (MRI) device, Computed Tomography (CT) device, camcorder, and microwave scanner), a navigation device, a Global navigation Satellite System (GNSS), an Event Data Recorder (EDR), a Flight Data Recorder (FDR), an automotive infotainment device, marine electronic equipment (such as marine navigation system and gyro compass), aviation electronics (avionics), an automotive head unit, an industrial or household robot, an Automatic Teller Machine (ATM), a Point Of Sales (POS) terminal, and an Internet-of-Things (IoT) device (such as electric bulb, sensor, sprinkler system, fire alarm system, temperature controller, street lamp, toaster, fitness equipment, hot water tank, heater, and boiler), or the like, but is not limited thereto.

According to an embodiment, examples of the electronic device may include furniture, a building/structure, a part of a vehicle, an electronic board, an electronic signature receiving device, a projector, and a sensor (such as water, electricity, gas, and electric wave meters), or the like, but is not limited thereto. According to certain embodiments, the electronic device may be flexible or a combination of at least two of the aforementioned devices. According to an embodiment, the electronic device is not limited to the aforementioned devices.

In the disclosure, the term “user” may denote a person who uses the electronic device or a device (e.g., artificial intelligent electronic device) which uses the electronic device.

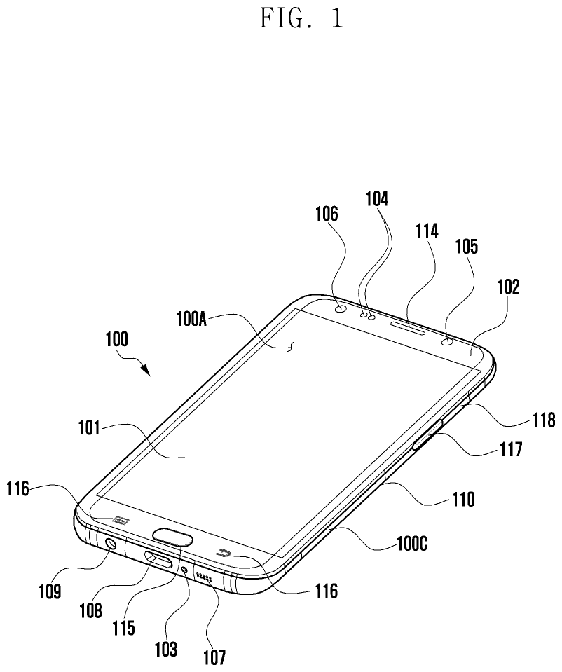

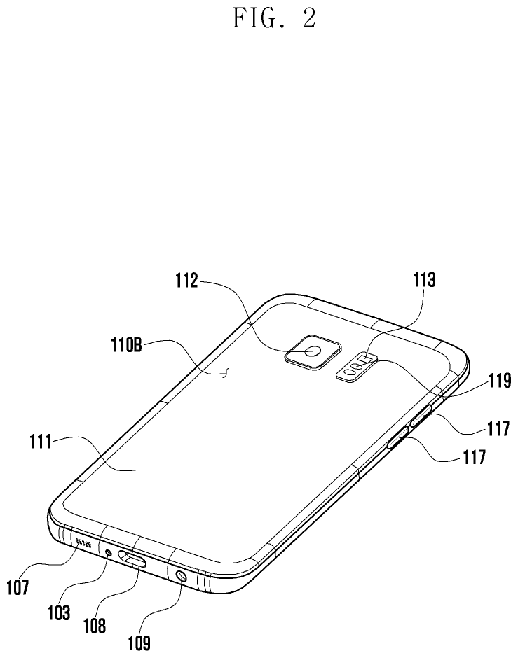

With reference to FIGS. 1 and 2, an electronic device 100 according to an embodiment may include a housing 110 including a first surface (or front surface) 110A, a second surface (or rear surface) 110B, and a side surface 110C enclosing a space between the first surface 110A and the second surface 110B. In another embodiment (not illustrated), the housing 110 may refer to a structure made up of part of the first surface 110A, second surface 110B, and side surface 110C of FIG. 1. According to an embodiment, the first surface 110A may be formed by a front plate 102 (e.g., a polymer plate or a glass plate including various coating layers) of which at least part is substantially transparent. The second surface 110B may be formed by a substantially opaque rear plate 111. The rear plate 111 may be made of, for example, coating or colored glass, ceramic, polymer, metal (e.g., aluminum, stainless steel (STS), or magnesium) or a combination of at least two of these materials. The side surface 110C may be coupled to the front plate 102 and the rear plate 111 and be formed by a side bezel structure (or “side member”) 118 including metal and/or polymer. In some embodiments, the rear plate 111 and the side bezel structure 118 may be integrally formed and be made of the same material (e.g., metal such as aluminum).

According to an embodiment, the electronic device 100 may include at least one of a display 101, audio modules 103, 107 and 114, sensor modules 104 and 119, camera modules 105, 112 and 113, key input device 117, indicator 106, and connector holes 108 and 109. In some embodiments, the electronic device 100 may omit at least one (e.g., the key input device 117 or the indicator 106) of the components or may additionally include other components.

The display 101, for example, may be exposed through a corresponding portion of the front plate 102. The display 101 may be coupled to or be disposed to be adjacent to a touch detection circuit, a pressure sensor that may measure the strength (the pressure) of a touch, and/or a digitizer that detects a stylus pen of a magnetic field type.

The audio modules 103, 107, and 114 may include a microphone hole 103 and speaker holes 107 and 114. The microphone hole 103 may provide outlet for a microphone that detects sound from outside the electronic device, and in some embodiments, a plurality of microphones may be disposed. The speaker holes 107 and 114 may include an external speaker hole 107 and a communication receiver hole 114. In some embodiments, the speaker holes 107 and 114 and the microphone hole 103 may be implemented into a single hole, or a speaker (e.g., piezo speaker) may be included without the speaker holes 107 and 114.

The sensor modules 104 and 119 may generate electrical signals or data values corresponding to operating states inside the electronic device 100 or external environment states. The sensor modules 104 and 119 may include, for example, a first sensor module 104 (e.g., a proximity sensor) and/or a second sensor module (not illustrated) (e.g., a fingerprint sensor) disposed on the first surface 110A of the housing 110. The sensor modules 104, 116, and 119 may further include a third sensor module 119 (e.g., heart rate monitor (HRM) sensor) and/or a fourth sensor module 116 (e.g., a fingerprint sensor) disposed on the second surface 110B of the housing 110. The fingerprint sensor may be disposed on the second surface 110B as well as the first surface 110A (e.g., home key button 115) of the housing 110. The electronic device 100 may further include other sensor modules, such as at least one of gesture sensor, gyro sensor, atmospheric pressure sensor, magnetic sensor, acceleration sensor, grip sensor, color sensor, infrared (IR) sensor, biometric sensor, temperature sensor, humidity sensor, or illuminance sensor 104.

The camera modules 105, 112, and 113 may include a first camera device 105 disposed on the first surface 110A of the electronic device 100 and a second camera device 112 disposed on the second surface 110B, and/or a flash 113. The camera devices 105 and 112 may include one or more lenses, image sensors, and/or image signal processors. The flash 113 may include, for example, a light emitting diode or a xenon lamp. In some embodiments, two or more lenses (infrared camera, wide angle and telephoto lens) and image sensors may be disposed on one surface of the electronic device 100.

The key input devices 115, 116, and 117 may include a home key button 115 disposed on the first surface 110A of the housing 110, a touch pad 116 disposed around the home key button 115, and/or a side key button 117 disposed on the side surface 110C of the housing 110. In another embodiment, the electronic device 100 may not include some or all of the above-mentioned key input devices 115, 116, and 117, and the key input devices 115, 116, and 117 which are not included, may be realized in different forms, such as a soft key, on the display 101.

The indicator 106, for example, may be disposed on the first surface 110A of the housing 110. The indicator 106, for example, may provide state information on the electronic device 100 in the form of light, and may include an LED.

The connector holes 108 and 109 may include a first connector hole 108 that may receive a connector (e.g., a universal serial bus (USB) connector) for transmitting and receiving power and/or data to and from an external electronic device and/or a second connector hole (e.g., an earphone jack) 109 that may receive a connector for transmitting and receiving an audio signal to and from an external electronic device.

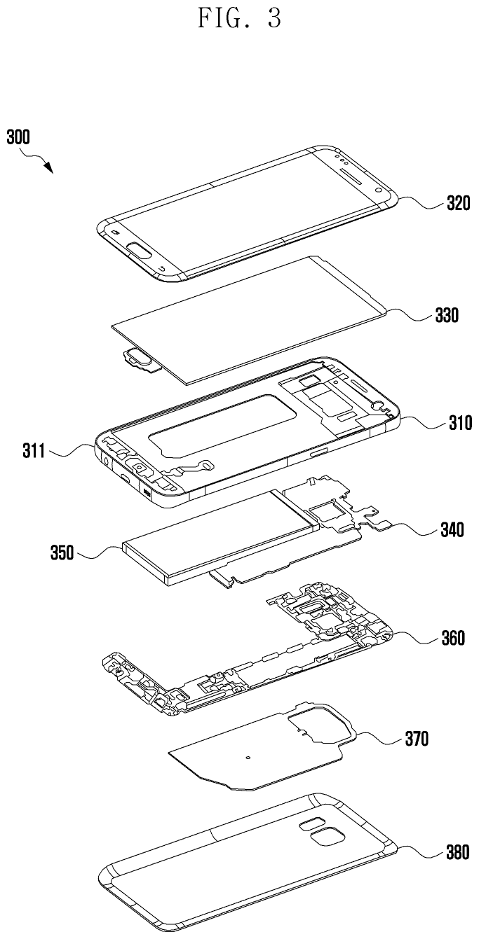

Referring to FIG. 3, an electronic device 300 (e.g., the electronic device 100 of FIG. 1) may include a side bezel structure 310, a first support member 311 (e.g., a bracket), a front plate 320, a display 330, a printed circuit board 340, a battery 350, a second support member 360 (e.g., a rear case), an antenna 370, and a rear plate 380. In some embodiments, at least one (e.g., the first support member 311 or the second support member 360) of the elements may be omitted from the electronic device 300 or another component may be additionally included in the electronic device 300. At least one of the components of the electronic device 300 may be the same as or similar to at least one of the components of the electronic device 100 of FIGS. 1 and 2, and a repeated description thereof will be omitted.

The first support member 311 may be disposed inside the electronic device 300 to be connected to the side bezel structure 310 or may be formed integrally with the side bezel structure 310. The first support member 311 may be made of, for example, a metal material and/or a non-metal (e.g., polymer) material. A display 330 may be coupled to one surface of the first support member 311, and a printed circuit board 340 may be coupled to the other surface of the first support member 311. On the printed circuit board 340, a processor, memory, and/or interface may be mounted. The processor may include, for example, at least one of a central processing unit, application processor, graphic processing unit, image signal processor, sensor hub processor, or communication processor.

The memory may include, for example, a volatile memory or a non-volatile memory.

The interface may include, for example, a high definition multimedia interface (HDMI), universal serial bus (USB) interface, secure digital (SD) card interface, and/or audio interface. The interface may, for example, electrically or physically connect the electronic device 300 with an external electronic device and may include a USB connector, an SD card/multi-media card (MMC) connector, or an audio connector.

The battery 350 is a device for supplying power to at least one component of the electronic device 300 and may include, for example, a non-rechargeable primary battery, a rechargeable secondary battery, or a fuel cell. At least part of the battery 350 may be disposed, for example, substantially flush with the printed circuit board 340. The battery 350 may be integrally disposed within the electronic device 300 and be detachably disposed from the electronic device 300.

The antenna 370 may be disposed between the rear plate 380 and the battery 350. The antenna 370, for example, may include a near field communication (NFC) antenna, a wireless charging antenna, and/or a magnetic secure transmission (MST) antenna. According to various embodiments, the NFC antenna, the wireless charging antenna, and/or the MST antenna may be realized by coils, and the NFC antenna, the wireless charging antenna, and/or the MST antenna may be integrated to be realized in the form of a combo coil. The electronic device 300, for example, may generate an NFC based frequency signal by using the NFC antenna or may generate an MST based frequency signal by using the MST antenna. The electronic device 300 may perform short distance communication based on the NFC based frequency signal and/or the MST based frequency signal generated by using the antenna 370. The electronic device 300 may wireless transmit and receive electric power that is necessary for charging to and from an external device by using the wireless charging antenna included in the antenna 370. In another embodiment, an antenna structure may be formed by one or a combination of the side bezel structure 310 and/or the first support member 311.

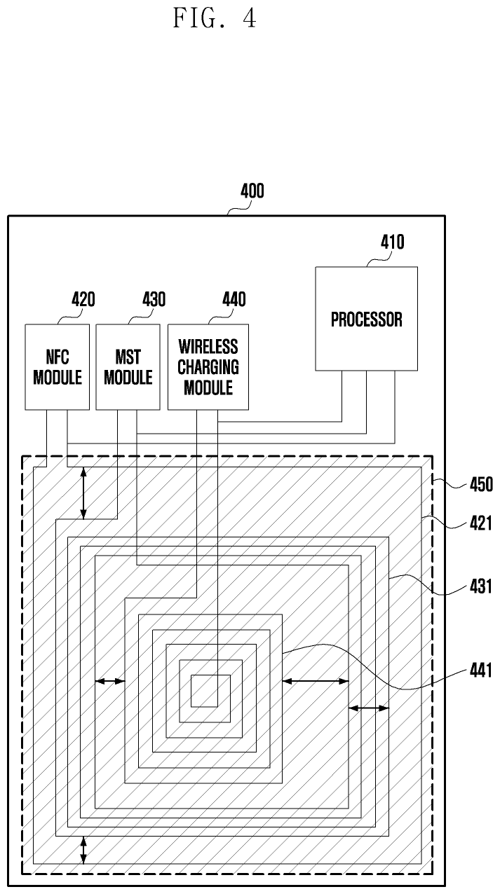

FIG. 4 is a view illustrating an internal structure of an electronic device, in which a plurality of coils are embedded, according to various embodiments.

Referring to FIG. 4, an electronic device 400 (e.g., the electronic device 100 of FIG. 1) may include a processor 410, an NFC module 420, an MST module 430, and a wireless charging module 440, and the modules may be controlled by a processor 410. According to an embodiment, the processor 410 may wirelessly communicate with another external electronic device by controlling the NFC module 420 and the MST module 430. According to an embodiment, the processor 410 may receive electric power from an external wireless charging device (e.g., a wireless power transmitter) by controlling the wireless charging module 440, and may charge an embedded battery (e.g., the battery 350 of FIG. 3) based on the received electric power.

According to various embodiments, the NFC module 420 may include an NFC coil 421, and may generate an NFC based frequency signal corresponding to the NFC coil 421. According to various embodiments, the MST module 430 may include an MST coil 431, and may generate an MST based frequency signal corresponding to the MST coil 431. The NFC based frequency signal and the MST based frequency signal may be utilized as a wireless payment system corresponding to the frequencies thereof. According to various embodiments, the electronic device 400 may be used as wireless payment units based on the NFC module 420 and the MST module 430. According to various embodiments, the wireless charging module 440 may include a wireless charging coil 441, and the electronic device 400 may be used as a wireless power receiver that receives electric power from an external wireless charging device based on the wireless charging module 440.

The intensities of the NFC based frequency signal and the MST based frequency signal may be offset by a metallic material (e.g., a battery, a printed circuit board, or a bracket) disposed around the electronic device 400. According to various embodiments, the electronic device 400 may include a first member 450 (e.g., a shielding sheet) corresponding to the NFC coil 421 and the MST coil 431 such that the intensities of the signals are not offset. According to various embodiments, the electronic device 400 may include an attractor to detect an external wireless charging device, and the attractor may be included in the first member 450. The first member 450 may at least partially function as the shielding sheet and the attractor.

According to various embodiments, the size of the first member 450 (e.g., the shielding sheet) may be determined based on the sizes of the NFC coil 421 and the MST coil 431. For example, the shielding sheet may be generally realized by 55×5 (about 5.5 cm×5.5 cm). The shielding sheet may include 5 nano crystalline layers (thickness: about 135 μm, 1 L: about 20 μm), and may be realized by a magnetic permeability of about 500 to 700 @ 100 KHz based on a nano crystalline material.

According to various embodiments, the first member 450 may include an attractor, and may overlap the shielding sheet such that the attractor is disposed based on a central portion thereof. For example, the attractor may include 5 nano amorphous layers (thickness: about 150 μm, 1 L: about 25 μm), and may be realized by a magnetic permeability of about 500 to 700 @ 250 KHz based on an amorphous material. The size of the attractor may be about 17 H. For example, the attractor may be circular, and the diameter thereof may be about 17 mm.

Table 1 is a comparison table of a nano crystalline material and an amorphous material.

TABLE 1

| | | Nano crystalline | Amorphous |
|---|---|---|---|
| | | material | material |
| Material | | Fe—Si- | Fe—Si- |
| | | based metal | based metal |
| Composition | Method | Melt spinning | Melt spinning |
| | | (Rapid cooling) | (Rapid cooling) |
| | Composition | Fe, Si, B, | Fe, Si, and B |
| | | Cu, and Nb | |
| | Saturated magnetic | 1.2 | 1.5 |
| | flux density (T) | | |
| Feature | Magnetic | 70,000 | 5,000 |
| | permeability (1 KHz) | | |
| | Coercivity (A/m) | <3 | <6 |
| | Electric resistance | 1.2 | 1.3 |
| | (μΩ · m) | | |

According to various embodiments, the shielding sheet and the attractor included in the first member 450 may be realized by a metallic material, and may be utilized as magnetic substances. In general, as the magnetic permeability of the metallic material increases, the magnetic intensity of the magnetic body also may increase. According to an embodiment, as the magnetic permeability of the shielding sheet increases, the performance for the MST based frequency signal also may be improved. In general, the shielding sheet may be realized by a magnetic permeability corresponding to about 500 to 700@100 KHz.

According to various embodiments, the first member 450 may be realized such that a magnetic force of at least about 500 Gauss (G) may be generated for an external metallic material. According to various embodiments, the first member 450 may include a shielding sheet and an attractor, and a magnetic force may be generated based on the materials corresponding to the shielding sheet and the attractor.

According to various embodiments, the electronic device 400 may include a first member 450 that may be utilized as one magnetic body while a magnet is not mounted in the interior of the electronic device 400. The first member 450 may be disposed adjacent to one surface (e.g., an upper surface or a front surface) of the electronic device 400 internally, or may be disposed adjacent to an opposite surface (e.g., a lower surface or a rear surface) of the electronic device 400. For example, the first member 450 may be disposed adjacent to a lower portion of a display panel (e.g., the display 330 of FIG. 3) of the electronic device 400, and the second member 450 may be disposed adjacent to an upper portion of a rear cover (e.g., the rear plate 380 of FIG. 3). According to various embodiments, the first member 450 may be disposed in correspondence to the front surface or the rear surface of the electronic device 400.

According to various embodiments, when the first member 450 is utilized as a magnetic body, it may be attached to or detached from another external magnetic body. The first member 450 may be realized such that a magnetic force of about 500 Gauss (G) or more is generated in order to be attached to or detached from another magnetic body. According to various embodiments, the other external magnetic body may be at least one accessory (e.g., an outer case, a holder, or a support of the electronic body). For example, a member that functions as a magnetic body is mounted in the interior of an outer case, and the first member 450 of the electronic device 400 and the member mounted on the outer case may be attached to or detached from each other. Members that function as a magnetic body may be mounted on the holder and the support in correspondence to contact points with the electronic device 400. The holder and the support may function as a holder and a support in correspondence to the electronic device 400 including the first member 450.

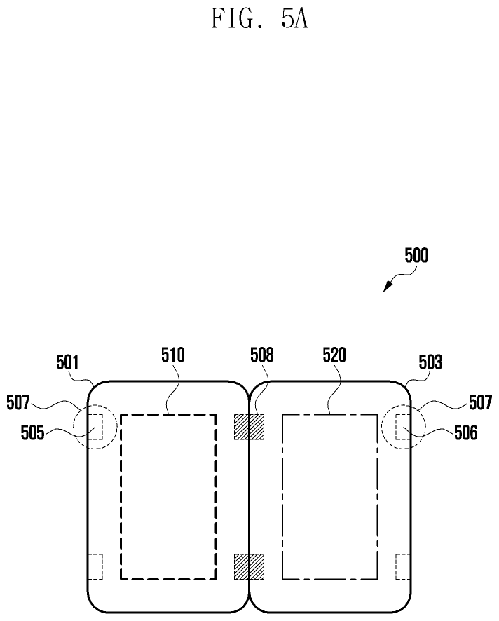

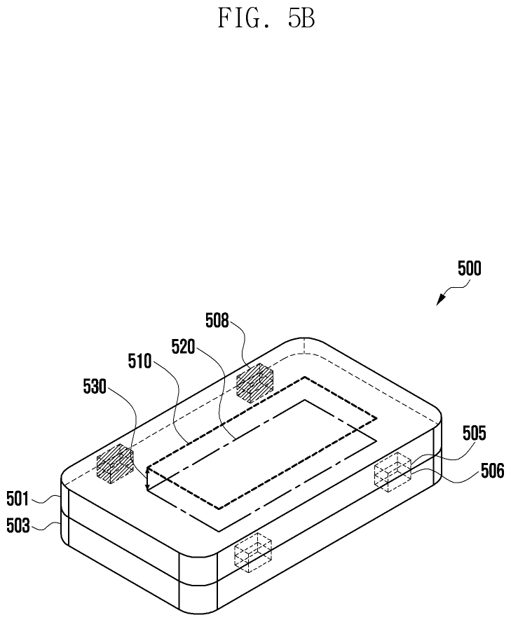

FIGS. 5A and 5B are views illustrating the interior of an electronic device, in which a space for disposing a magnet is secured, according to various embodiments.

Referring to FIG. 5A, an electronic device 500 (e.g., the electronic device 100 of FIG. 1) may include at least a portion of a metallic material that may be utilized as a magnetic body (e.g., the first magnetic body 510). According to various embodiments, the electronic device 500 may be a foldable electronic device, and may be an electronic device that is divided into a first housing 501 (e.g., the first body) and a second housing 503 (e.g., the second body). The first housing 501 and the second housing 503 may be folded by a hinge unit 508. For example, the first housing 501 and the second housing 503 may be folded in one direction or an opposite direction, and the folding direction is not limited to one direction.

According to various embodiments, the first housing 501 may be at least partially utilized as a magnetic body based on a metallic material (e.g., a shielding sheet for maintaining the intensities of the NFC based frequency and the MST based frequency or an attractor for supporting a wireless charging scheme) included in the interior thereof. According to various embodiments, the metallic material included in the housing 501 may be at least a first magnetic body 510.

According to various embodiments, the second housing 503 may include a metallic material in the interior thereof. For example, the second housing 503 may include a magnet disposed adjacent to one surface (e.g., a front surface or a rear surface) of the electronic device 500. An antenna may be disposed in the interior of the second housing 503, and the location of the magnet may be determined based on the arrangement structure of the antenna. According to various embodiments, the magnet included in the second housing 503 may be a second magnetic body 520.

According to various embodiments, a magnetic force of at least about 500 Gauss (G) or more is necessary between the first magnetic body 510 and the second magnetic body 520, and the sizes and the arrangement structure of the first magnetic body 510 and 520 may be determined such that a magnetic force of at least about 500 Gauss (G) or more may be generated. For example, the metallic material that functions as the first magnetic body 510 may be realized by a size, by which a magnetic force of at least about 500 Gauss (G) or more may be generated.

According to another embodiment, the first magnet 505 may be included in the first housing 501, and the second magnet 506 may be included in the second housing 503. According to various embodiments of the disclosure, because neither the first magnet 505 nor the second magnet 506 is mounted in the interior of the electronic device 500, the interior space, in which the first magnet 505 and the second magnet 506 are located, may be identified. According to various embodiments, an antenna (e.g., an antenna corresponding to LTE main, LTE sub, Wi-Fi, BT, or GPS) may be additionally disposed based on the secured interior space.

Referring to FIG. 5B, the foldable electronic device 500 may be folded in one direction, and the first housing 501 and the second housing 503 may at least partially function as magnetic bodies to maintain the folded shape. According to various embodiments, if the first magnetic body 510 of the first housing 501 is located at an upper end of the electronic device 500 internally, the second magnetic body 520 of the second housing 503 also may be located at an upper end of the electronic device 500. The second magnetic body 520 may be disposed to correspond to the location of the first magnetic body 510. According to various embodiments, the arrangement locations of the first magnetic body 510 and the second magnetic body 520 may be determined such that the magnetic forces of the first magnetic body 510 and the second magnetic body 520 are maintained at about 500 Gauss (G) or more.

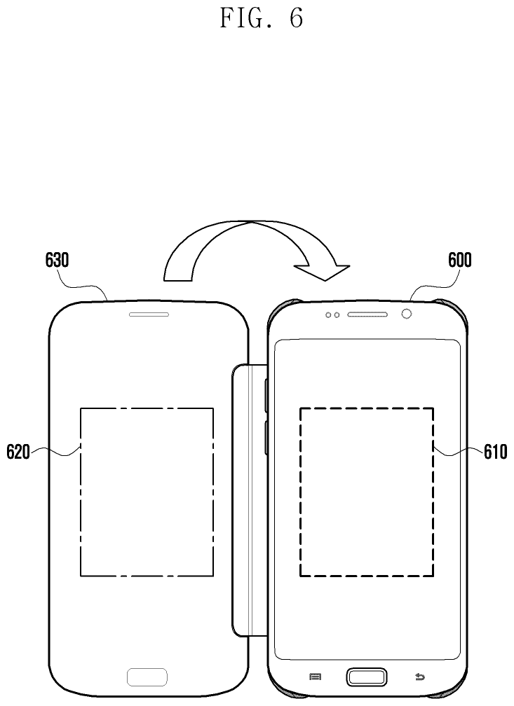

FIG. 6 is an exemplary view of a method of disposing a magnet in a front cover of an external case and utilizing a metallic material embedded in an electronic device as a magnetic body according to various embodiments when the front cover is folded to be adjacent to a rear surface of the electronic device.

Referring to FIG. 6, an electronic device 600 may be attached to an outer case corresponding to an accessary. The outer case includes a front cover 630 (e.g., a first cover) for protecting a display, on which a screen of the electronic device 600 is displayed, and a rear cover (e.g., a second cover) for fixing the electronic device 600. According to various embodiments, the electronic device 600 may include a shielding sheet and an attractor corresponding to a metallic material such that the shielding sheet and the attractor may be used as a magnetic body. For example, the shielding sheet and the attractor corresponding to the metallic material may be first magnetic body 610. A magnet 620 may be at least partially included in a front cover 630 of the outer case, and the magnet 620 may be utilized as the second magnetic body 620.

According to various embodiments, the first magnetic body 610 may be disposed adjacent to the rear side (e.g., a rear surface of the electronic device 600) of the electronic device 600, and when the front cover 630 of the outer case is folded adjacent to the rear surface of the electronic device 600, the first magnetic body 610 and the magnet 620 (e.g., the second magnetic body) included in the outer case may be attached to each other. According to various embodiments, the first magnetic body 610 may be disposed adjacent to the front side (e.g., a front surface of the electronic device 600) of the electronic device 600, and when the front cover 630 of the outer case is folded adjacent to the front surface of the electronic device 600, the first magnetic body 610 and the magnet 620 included in the outer case may be attached to each other.

According to various embodiments, the arrangement structure of the first magnetic body 610 and the second magnetic body 620 may be determined in correspondence to the locations thereof. For example, the arrangement structure of the first magnetic body 610 may be determined based on the arrangement location of the second magnetic body 620. The arrangement structure of the second magnetic body 620 may be determined based on the arrangement location of the first magnetic body 610.

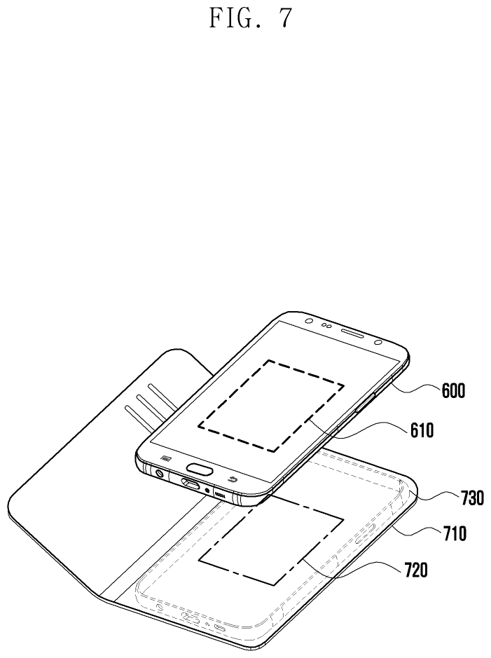

FIG. 7 is an exemplary view of a method of disposing a magnet in a rear cover of an external case and utilizing a metallic material embedded in an electronic device as a magnetic body according to various embodiments.

Referring to FIG. 7, an electronic device 600 may be attached to an outer case corresponding to an accessary. According to various embodiments, the electronic device 600 may include a shielding sheet and an attractor corresponding to metallic materials such that the shielding sheet and the attractor may be used as magnetic bodies. For example, the shielding sheet and the attractor corresponding to the metallic materials may be first magnetic body 610. A magnet 720 may be included in a rear cover 710 of the outer case, and the magnet 720 may be utilized as the second magnetic body 720. According to various embodiments, the first magnetic body 610 may be disposed adjacent to the rear side (e.g., a rear surface of the electronic device 600) of the electronic device 600, and when the electronic device 600 is disposed on the rear cover 710 of the outer case, the first magnetic body 610 and the magnet 720 (e.g., the second magnetic body) included in the rear cover 710 of the outer case may be attached to each other.

According to various embodiments, the fixing member 730 (e.g., a jelly case or a fixing structure fixed to a side surface of the electronic device) realized on the rear cover 710 of the outer case to fix the electronic device 600 may be omitted. According to various embodiments, because the first magnetic body 610 embedded in the electronic device 600 and the magnet 720 disposed in the rear cover 710 of the outer case are attached to each other, the location of the electronic device 600 may be fixed without using the fixing member 730. According to various embodiments, the sizes and the arrangement locations of the first magnetic body 610 and the second magnetic body 720 may be determined such that the locations of the first magnetic body 610 and the second magnetic body 720 are fixed based on the magnetic force generated between the first magnetic body 610 and the second magnetic body 720.

According to various embodiments, an electronic device may include at least one coil, a circuit board, and a first member disposed between the at least one coil and the circuit board in correspondence to the at least one coil, and the first member is attached to a second member including a metallic material or is detached from the second member.

According to various embodiments, the at least one coil may include at least one of a near field communication (NFC) coil for performing short distance wireless communication, a magnetic secure transfer (MST) coil, and a wireless charging coil for performing a wireless charging function.

According to various embodiments, the first member may include a shielding sheet for preventing lowering of the performance of the short distance wireless communication and an attractor for receiving electric power from the wireless charging device.

According to various embodiments, the magnetic permeability of the shielding sheet may be realized by 500 to 700@100 KHz and the magnetic permeability of the attractor is realized by 500@250 KHz.

According to various embodiments, the strength of a magnetic force may increase as the magnetic permeability increases, and a magnetic force of at least 500 G or more may be generated in the first member in correspondence to the second member.

According to various embodiments, the size of the first member may be determined based on an arrangement structure of the at least one coil.

According to various embodiments, the first member may be embedded adjacent to at least one of a front surface or a rear surface of the electronic device.

According to various embodiments, the first member may be embedded at an upper end portion or a lower end portion of a screen of the electronic device.

According to various embodiments, the electronic device may further include a case attached to the electronic device in correspondence to the electronic device, and the case may include a first cover configured to protect a front surface of the electronic device or a second cover configured to protect a rear surface of the electronic device.

According to various embodiments, the second member may be included in at least one of the first cover or the second cover.

According to various embodiments, when the second member is included in the second cover, a fixing member disposed on an outer surface of the second surface to fix the electronic device may be removed.

According to various embodiments, the electronic device may further include a first housing and a second housing defining an external appearance of the electronic device, a hinge unit connecting the first housing and the second housing such that the first housing and the second housing are folded, a first magnetic body disposed in the interior of the first housing, and a second magnetic body disposed in the interior of the second housing and magnetically coupled to the first magnetic body when the first housing and the second housing are folded.

According to various embodiments, the second housing may further include an antenna disposed in the interior thereof, and the second magnetic body may be disposed in correspondence to the antenna.

According to various embodiments, the second magnetic body may be disposed in correspondence to the antenna or may be disposed to correspond to a location of the first magnetic body when the first housing and the second housing are folded.

According to various embodiments, the size and the arrangement location of the second magnetic body may be determined based on a magnetic force generated in correspondence to the first magnetic body.

According to various embodiments, the first magnetic body may include at least one of a shielding sheet for preventing lowering of the performance of the short distance wireless communication of the electronic device, and an attractor for receiving electric power from the wireless charging device.

According to various embodiments, the shielding sheet may be an Fe—Si-based metallic material and includes Fe, Si, B, Cu, and Nb, and the attractor may be an Fe—Si-based metallic material and includes Fe, Si, and B.

According to various embodiments, the electronic device may further include a display divided into a first display area and a second display area and folded with respect to a border line between the first display area and the second display area, a circuit board including at least one coil in correspondence to the first display area, and a first member attached to the circuit board in correspondence to the at least one coil, and the first member may be attached the second member that is a metallic material included in the second display area when the display is folded or is detached from the second member.

According to various embodiments, the second member may be disposed in correspondence to the second display area to correspond to a location of the first member when the display is folded.

The term “module” used in this disclosure may refer to a certain unit that includes one of hardware, software and firmware or any combination thereof. The module may be interchangeably used with unit, logic, logical block, component or circuit, for example. The module may be the minimum unit, or part thereof, which performs one or more particular functions. The module may also be formed mechanically or electronically. For example, the module disclosed herein may include at least one of an application-specific integrated circuit (ASIC) chip, field-programmable gate arrays (FPGAs), and programmable-logic device, which have been known or are to be developed. At least part of the device (e.g., modules or functions thereof) or method (e.g., operations) according to various embodiments may be implemented as commands stored, e.g., in the form of program modules, in a computer-readable storage medium. In case commands are executed by at least one processor, this processor may then be configured to perform a particular function corresponding to the commands. The computer-readable storage medium may be, for example, the memory. At least some of the program modules may be implemented (e.g., executed) by, for example, the processor. At least some of the program modules may include, for example, a module, a program, a routine, a set of instructions, and/or a process for performing one or more functions. The non-transitory computer-readable recording medium may include magnetic media such as a hard disk, a floppy disk, and a magnetic tape, optical media such as a compact disc-ROM (CD-ROM) and a DVD, magneto-optical media such as a floptical disk, and hardware devices specially configured to store and perform a program instruction. In addition, the program instructions may include high class language codes, which can be executed in a computer by using an interpreter, as well as machine codes made by a compiler. The aforementioned hardware device may be configured to operate as one or more software modules in order to perform the operation of various embodiments of this disclosure, and vice versa. A module or programming module according to various embodiments may include or exclude at least one of the above-discussed elements or further include other elements or combinations thereof. The operations performed by the module, programming module or any other element according to various embodiments may be executed sequentially, in parallel, repeatedly, or by a heuristic method. Additionally, some operations may be executed in different orders or omitted, or other operations may be added.

1. An electronic device comprising:
at least one coil;
a circuit board; and
a first member disposed between the at least one coil and the circuit board in correspondence to the at least one coil,
wherein the first member is attached to a second member comprising a metallic material or is detached from the second member.

2. The electronic device of claim 1, wherein the at least one coil comprises at least one of a near field communication (NFC) coil for performing short distance wireless communication, a magnetic secure transfer (MST) coil, and a wireless charging coil for performing a wireless charging function.

3. The electronic device of claim 2, wherein the first member comprises a shielding sheet for preventing lowering of the performance of the short distance wireless communication and an attractor for receiving electric power from the wireless charging device.

4. The electronic device of claim 3, wherein the shielding sheet is an Fe—Si-based metallic material and comprises Fe, Si, B, Cu, and Nb, and the attractor is an Fe—Si-based metallic material and comprises Fe, Si, and B.

5. The electronic device of claim 3, wherein the magnetic permeability of the shielding sheet is realized by 500 to 700@100 KHz and the magnetic permeability of the attractor is realized by 500@250 KHz.

6. The electronic device of claim 5,
wherein the strength of a magnetic force increases as the magnetic permeability increases, and
wherein a magnetic force of at least 500 G or more is generated in the first member in correspondence to the second member.

7. The electronic device of claim 1, wherein the size of the first member is determined based on an arrangement structure of the at least one coil, or the first member is embedded adjacent to at least one of a front surface or a rear surface of the electronic device or is embedded at an upper end portion or a lower end portion of a screen of the electronic device.

8. The electronic device of claim 1, further comprising:
a case attached to the electronic device in correspondence to the electronic device,
wherein the case comprises a first cover configured to protect a front surface of the electronic device or a second cover configured to protect a rear surface of the electronic device.

9. The electronic device of claim 8,
wherein the second member is included in at least one of the first cover or the second cover, and
wherein when the second member is included in the second cover, a fixing member disposed on an outer surface of the second surface to fix the electronic device is removed.

10. The electronic device of claim 1, further comprising:
a first housing and a second housing defining an external appearance of the electronic device;
a hinge unit connecting the first housing and the second housing such that the first housing and the second housing are folded;
a first magnetic body disposed in the interior of the first housing; and
a second magnetic body disposed in the interior of the second housing and magnetically coupled to the first magnetic body when the first housing and the second housing are folded.

11. The electronic device of claim 10,
wherein the second housing further comprises an antenna disposed in the interior thereof, and
wherein the second magnetic body is disposed in correspondence to the antenna or is disposed to correspond to a location of the first magnetic body when the first housing and the second housing are folded, or the size and the arrangement location of the second magnetic body are determined based on a magnetic force generated in correspondence to the first magnetic body.

12. The electronic device of claim 10, wherein the first magnetic body comprises at least one of:
a shielding sheet for preventing lowering of the performance of the short distance wireless communication of the electronic device; and
an attractor for receiving electric power from the wireless charging device.

13. The electronic device of claim 12, wherein the shielding sheet is an Fe—Si-based metallic material and comprises Fe, Si, B, Cu, and Nb, and the attractor is an Fe—Si-based metallic material and comprises Fe, Si, and B.

14. The electronic device of claim 1, further comprising:
a display divided into a first display area and a second display area and folded with respect to a border line between the first display area and the second display area;
a circuit board comprising at least one coil in correspondence to the first display area; and
a first member attached to the circuit board in correspondence to the at least one coil,
wherein the first member is attached the second member that is a metallic material included in the second display area when the display is folded or is detached from the second member.

15. The electronic device of claim 14, wherein the second member is disposed in correspondence to the second display area to correspond to a location of the first member when the display is folded.
